(19) United States
(12) Patent Application Publication
(10) Pub. No.: US 2008/0151985 A1
(43) Pub. Date: Jun. 26, 2008

(54) NETWORK-ASSISTED BTS RECEIVER PERFORMANCE OPTIMIZATION

(75) Inventors: Ke-Kang Chin, Bartlett, IL (US); Joseph J. Schuler, Roselle, IL (US); R. Scott Swenson, Hoffman Estates, IL (US)

Correspondence Address: MOTOROLA, INC., 1303 EAST ALGONQUIN ROAD, IL01/3RD, SCHAUMBURG, IL, 60196, US

(73) Assignee: MOTOROLA, INC., Schaumburg, IL (US)

(21) Appl. No.: 11/616,151

(22) Filed: Dec. 26, 2006

(51) Int. Cl. H03H 7/40

(52) U.S. Cl. 375/231

(57) ABSTRACT

A wireless communication system (100), method, and base station (112) are provided for optimizing performance of a base station receiver (120). The method includes selecting an interpolation matrix (216) specially tailored for particular channel characteristics from a pre-defined set of interpolation matrices (218), and using the selected interpolation matrix in the channel estimation, and applying the derived channel estimates for the data subcarriers to an equalizer (118) as a set of weights. The interpolation matrix (216) is selected by using the matrix corresponding to a received channel profile information, or by monitoring a performance metric (212) while using each interpolation matrix of a pre-defined set of matrices in the channel estimation and applying the derived channel estimates for the data subcarriers as a set of weights to the receiver equalizer (118) and selecting the matrix resulting in best performance.

### FIELD OF THE INVENTION

The present invention generally relates to the field of wireless communications, and more particularly relates to optimizing BTS receiver performance with assistance from the network in wireless communication systems.

### BACKGROUND OF THE INVENTION

In WiMAX 802.16e and GSM/EDGE receivers, as an example, equalizers are often used in fighting against channel impairment. Many factors characterize a particular channel. For instance, the terrain surrounding the receiver and the transmitter will influence the channel behavior. A receiver located in a hilly or mountainous environment will perform differently than one located on relatively flat terrain. Additionally, a receiver located in an urban area, which has many interfering buildings and other competing signals, encounters different channel characteristics than one located in a rural environment.

However, the equalizers used on each receiver must accommodate a wide variety of channel conditions because the channel characteristics vary by location. These characteristics are generally not known a-priori. The variety in channel conditions is typically dealt with by attempting to measure some characteristic of the channel and then adapt the equalizer's characteristics to that channel in real time. The algorithms used to measure and adapt to the channel are subject to degradations caused by noise and interference unless the range of adaptation is constrained by a-priori knowledge of the channel characteristics likely to be seen in a given location. These degradations resulting from not constraining the adaptation to locally expected channel characteristics generally results in less than optimum adaptation of the equalizer and degraded performance when compared to an equalizer whose adaptation might be constrained to a subset of all possible channel conditions. To accommodate all possible channel conditions, the algorithms required by the equalizer in a receiver can result in a high complexity design which in turn can be costly to implement. One possible solution is to constrain the complexity. Since there are many different kinds of channel types, with a constrained complexity design, the equalizer is forced to use a set of compromised common parameters for all conditions without the knowledge of a specific channel condition. This often translated into compromised receiver performance.

Therefore a need exists to overcome the problems with the prior art as discussed above.

### SUMMARY OF THE INVENTION

Briefly, in accordance with the present invention, disclosed is a wireless communication system, and method, for optimizing performance of a base station receiver. The method includes providing the base station with information about the local channel characteristics, selecting an interpolation matrix from a pre-defined set of interpolation matrices, used together with the real-time calculated channel estimates of pilot or synchronization information to compute the channel estimates for the received data, and applying these channel estimates to an equalizer as a set of weights to correct the channel-induced distortions in the received data.

Pre-defined interpolation matrices are available to the receiver's equalizer that provide for improved data channel estimation in one or more different channel conditions. The desired interpolation matrix is selected from the pre-defined set of interpolation matrices in one of two ways. In one embodiment of the present invention, by receiving channel profile information for the base station receiver and selecting an optimal interpolation matrix from a pre-defined set of interpolation matrices, a matrix is selected that corresponds to the received channel profile information. In another embodiment of the present invention, the desired interpolation matrix may be selected based on a reception of either a known test signal or regular traffic data and a determination of which interpolation matrix optimizes a performance metric for the base station receiver or the system operation.

The performance metric can be a bit error rate, a symbol error rate, a frame error rate for a known received data signal transmitted by a mobile during a test drive, or standard network statistics such as the number of dropped calls, percentage of calls dropped, number of access failures, and percentage of access failures for normal received data signal during operation, or other relevant system performance metrics that are affected by the equalizer operation, or combinations of the above.

The received data signal may be either a known test signal or normal network traffic. Additionally, the base station receiver uses at least one of CDMA, TDMA (e.g., GSM, EDGE, and GPRS), FDMA, and OFDM (e.g., WiMAX) protocols or any air interface that advantageously utilizes a receiver channel equalizer to enhance the receiver's performance.

### BRIEF DESCRIPTION OF THE DRAWINGS

The accompanying figures where like reference numerals refer to identical or functionally similar elements throughout the separate views, and which together with the detailed description below are incorporated in and form part of the specification, serve to further illustrate various embodiments and to explain various principles and advantages all in accordance with the present invention.

FIG. 1 is block diagram illustrating a wireless communications system according to an embodiment of the present invention;

FIG. 2 is a block diagram illustrating a base station according to an embodiment of the present invention;

FIG. 3 is a block diagram illustrating an exemplary one-tap equalizer according to an embodiment of the present invention;

FIG. 4 is graphical representation of an uplink PUSC tile structure for the 802.16e OFDMA air interface having four pilot carriers;

FIG. 5 is an operational flow diagram illustrating a process of optimizing base station receiver performance using network assistance according to an embodiment of the present invention;

FIG. 6 is an operational flow diagram illustrating another process of optimizing base station receiver performance using network assistance, for an example in an 802.16e system application, according to an embodiment of the present invention;

FIG. 7 is an operational flow diagram illustrating another process of optimizing base station receiver performance using network assistance, for an example in a GSM/EDGE system application, according to an embodiment of the present invention;

FIG. 8 is a graphical performance comparison of pre-calculated interpolation matrices in AWGN channel condition for uplink PUSC mode of an 802.16e OFDMA air interface according to an embodiment of the present invention;

FIG. 9 is a graphical performance comparison of pre-calculated interpolation matrices in TU 3 kmph channel condition for uplink PUSC mode of an 802.16e OFDMA air interface according to an embodiment of the present invention

FIG. 10 is a graphical performance comparison of pre-calculated interpolation matrices in AWGN channel condition for uplink AMC 2×3 mode of the 802.16e OFDMA air interface according to an embodiment of the present invention;

FIG. 11 is a graphical performance comparison of pre-calculated interpolation matrices in TU 3 kmph channel condition for uplink AMC 2×3 mode of the 802.16e OFDMA air interface according to an embodiment of the present invention.

### DETAILED DESCRIPTION

As required, detailed embodiments of the present invention are disclosed herein; however, it is to be understood that the disclosed embodiments are merely examples of the invention, which can be embodied in various forms. Therefore, specific structural and functional details disclosed herein are not to be interpreted as limiting, but merely as a basis for the claims and as a representative basis for teaching one of ordinary skill in the art to variously employ the present invention in virtually any appropriately detailed structure. Further, the terms and phrases used herein are not intended to be limiting; but rather, to provide an understandable description of the invention.

The terms “a” or “an”, as used herein, are defined as one or more than one. The term plurality, as used herein, is defined as two or more than two. The term another, as used herein, is defined as at least a second or more. The terms including and/or having, as used herein, are defined as comprising (i.e., open language). The term coupled, as used herein, is defined as connected, although not necessarily directly, and not necessarily mechanically.

The term wireless communication device is intended to broadly cover many different types of devices that can wirelessly receive signals, and optionally can wirelessly transmit signals, and may also operate in a wireless communication system. For example, and not for any limitation, a wireless communication device can include any one or a combination of the following: a cellular telephone, a mobile phone, a smartphone, a two-way radio, a two-way pager, a wireless messaging device, a laptop/computer, automotive gateway, residential gateway, and the like.

Wireless Communications System

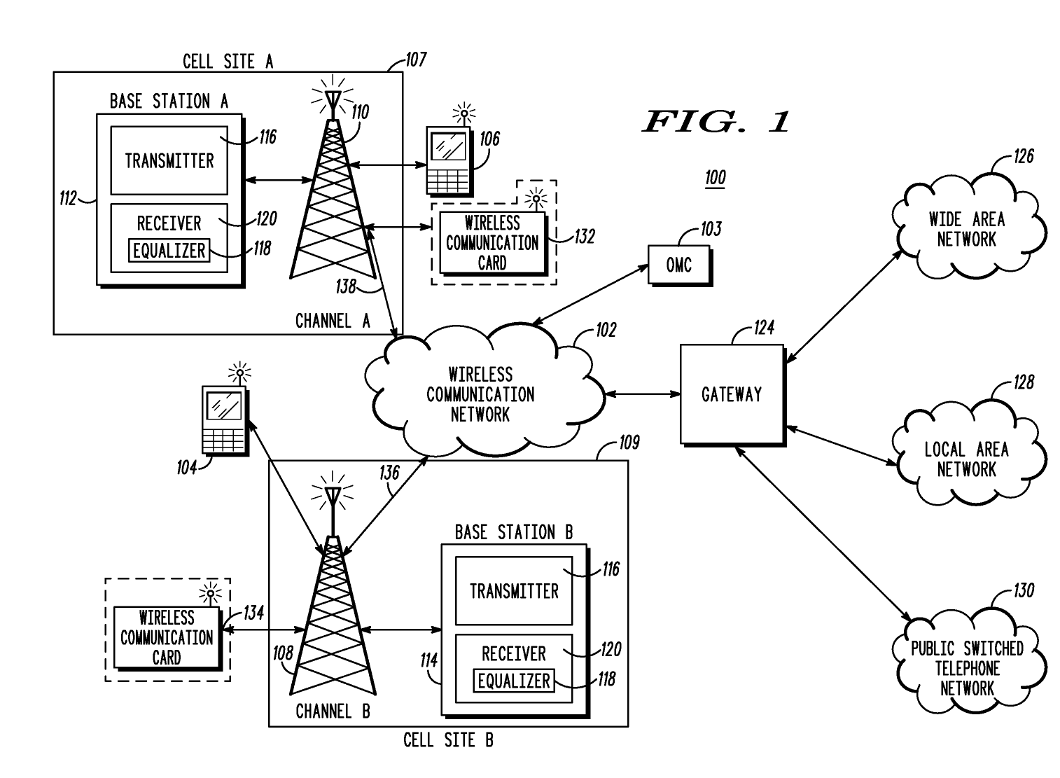

According to an embodiment of the present invention, as shown in FIG. 1, a wireless communications system 100 is illustrated. FIG. 1 shows a wireless communications network 102 that connects wireless communication devices 104, 106, 132, 134 to other wireless communication devices and/or to other networks such as a wide area network 126, a local area network 128, a public switched telephone network 130, and the like via a gateway 124. The wireless communication network 102 also operatively connects an operations and maintenance center (OMC) 103 to base stations 112 and 114 for various maintenance and operational purposes, including downloading of software and other information or parameters relevant to the operation of the base stations. The OMC 103 also retrieves relevant information about the operational status of the base stations including performance metrics that are used to assess the operational status of the base stations. This exchange of the information and parameters can also be performed with a local maintenance terminal coupled to the base station. The local maintenance terminal would be operated typically by service personnel that are generally in some proximity to the base station site. The wireless communications network 102, in this example, comprises a mobile phone network, a mobile text messaging device network, a pager network, or the like.

Further, in this example, the communications standard of the wireless communications network 102 shown in FIG. 1 comprises Code Division Multiple Access (CDMA), Time Division Multiple Access (TDMA) such as Global System for Mobile Communications (GSM), Enhanced Data GSM Environment (EDGE), and General Packet Radio Service (GPRS), Frequency Division Multiple Access (FDMA), Orthogonal Frequency Division Multiplexing (OFDM) such as 802.16e (WiMAX), or the like. Additionally, the wireless communications network 102 also comprises text messaging standards, for example, Short Message Service (SMS), Enhanced Messaging Service (EMS), Multimedia Messaging Service (MMS), or the like. The wireless communications network 102 also allows for push-to-talk over cellular communications between capable wireless communication devices.

The wireless communications network 102 supports any number of wireless communication devices 104, 106, 132, 134. The support of the wireless communications network 102 includes support for mobile telephones, smart phones, text messaging devices, handheld computers, pagers, beepers, wireless communication cards, or the like. A smart phone is a combination of 1) a pocket PC, handheld PC, palm top PC, or Personal Digital Assistant (PDA), and 2) a mobile telephone. More generally, a smartphone can be a mobile telephone that has additional application processing capabilities. The wireless communication cards 132, 134, in one embodiment, reside within an information processing system as shown by the dashed lines. The information processing system, in one embodiment, can be a personal computer, a personal, digital assistant, a smart phone, and the like.

In one embodiment, the wireless communications network 102 is capable of broadband wireless communications utilizing time division duplexing (“TDD”) as set forth, for example, by the IEEE 802.16e (WiMAX) standard. The duplexing scheme TDD allows for the transmissions of signals in a downstream and upstream direction using a single RF frequency channel by separating the upstream and downstream transmissions in time. It should be noted that the present invention is not limited to an 802.16e system for implementing TDD. Furthermore, the wireless communications system 100 is not limited to a system using only a TDD scheme. For example, Frequency Division Duplexing (“FDD”) systems use a different RF frequency for transmission in each direction between the base station and the wireless communication devices. One example, using TDMA and FDMA as in GSM networks may be used for a portion of the available communication channels in the system 100, while one or more schemes are used for the remaining communication channels.

The wireless communications system 100 also includes a group of cell sites 107, 109 that may be, for example, synchronized to a common synchronization scheme. The base stations 112, 114, in one embodiment, are connected to the wireless communication network 102 via an Ethernet connection 136, 138. However, it should be noted that other networking communication standards can be used. The synchronization, in one embodiment, is a time-based synchronization for transmitting and/or receiving wireless data. For example, in a wireless communications system using TDD (e.g. where transmitting and receiving is performed on the same RF frequency channel), synchronization between the base stations is necessary so that their respective wireless communication devices 104, 106, 132, 134 are not transmitting while the other wireless devices in the group are receiving and vice-versa. If this situation occurs, interference between the wireless devices 104, 106 can be created. Each cell site 107, 109, in one embodiment, includes a base station 112, 114 that provides wireless communication services to a coverage area associated with the cell site.

Each base station 112, 114 includes, in one embodiment, a transmitter 116 and a receiver 120. Each receiver 120 also includes at least one equalizer 118 for removing channel distortion. The equalizer 118 will be discussed in further detail below.

The wireless communication devices 104, 106, 132, 134, in one embodiment, are capable of wirelessly communicating data using the 802.16e standard or any other communication scheme that supports TDD. In another embodiment, the wireless communication devices 104, 106, 132, 134 are capable of wireless communications using other access schemes in place of or in addition to TDD. One example is using TDMA communication such as for a GSM/EDGE system application.

Each cell site 107, 109 can be located in a variety of environments, which will affect the quality of the data signals received. A large number of reflecting structures, such tall buildings or mountains, will increase the possible number of paths that a signal can reach the receiving antenna, thereby increasing the multi-path distortion. Additionally, other interfering signals in the area can distort the signal or cause further unwanted signal quality degradation. For instance, in FIG. 1, base station 112 is assigned to channel A, while base station 114 operates on channel B. Channel A can be a large, urban area, containing numerous tall buildings, interfering signals, and having an amount of subscribers that is near the maximum system capacity. On the other hand, channel B could be located in a small, rural town, where there are relatively few subscribers, interfering signals, or reflective structures (e.g., buildings or mountains) that increase multi-path interference. Thus, the amount of distortion created by each channel will differ based on the surrounding terrain and system characteristics.

Base Station Information Processing System

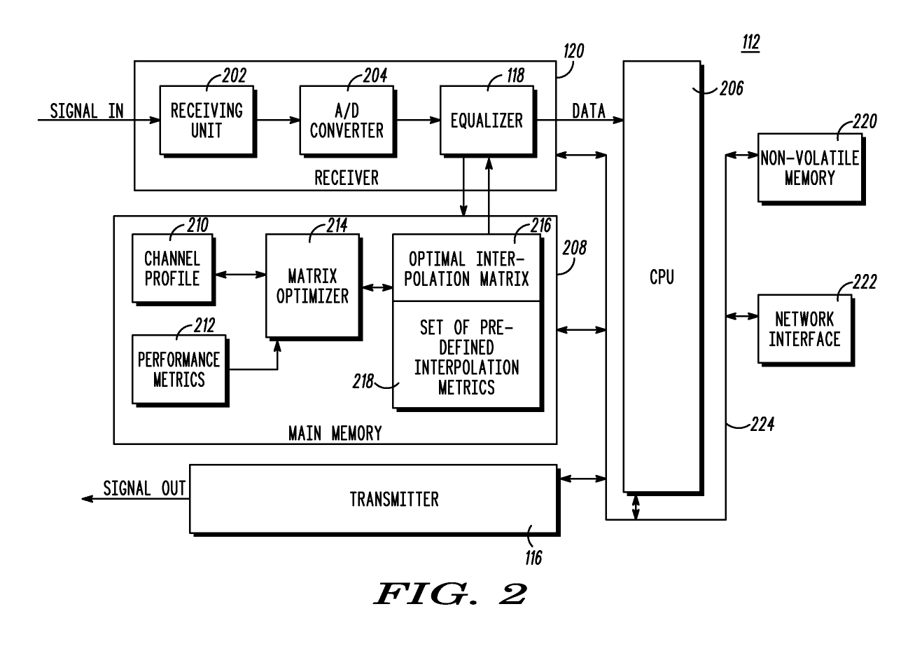

FIG. 2 is a block diagram illustrating a more detailed view of the base station 112 according to an embodiment of the present invention. One of ordinary skill in the art realizes that the description provided herein of base station 112 similarly applies to base station 114. The base station 112, in one embodiment, resides within its respective cell site 107. In another embodiment, the base station 112 resides outside of and is communicatively coupled to its respective cell site 107. The base station 112 includes one or more processors 206 that are communicatively connected to a main memory 208 (e.g., volatile memory), a transmitter 116, a receiver 120, non-volatile memory 220, and a network adapter hardware 222. A system bus 224 interconnects these system components. The receiver 120 includes a receiving unit 202 for receiving a data signal, communicatively coupled to an A/D converter 204 for transforming the received signal into digital information, and an equalizer 118 for removing any distortion from the signal that was encountered from traveling through the channel. The main memory 208 includes a channel profile 210, a matrix optimizer 214, performance metrics 212, and a set of pre-defined interpolation matrices 218, including an optimal interpolation matrix 216 that is used in the channel estimation and subsequently in the equalization process. In one embodiment, the matrix optimizer 214 is configured to operate according to an algorithm that can be executed in the CPU 206. Parameters for these components can reside in the main memory 208. In another embodiment, these components can be hardware components residing outside of the main memory 208.

Example Of Equalizer Operation

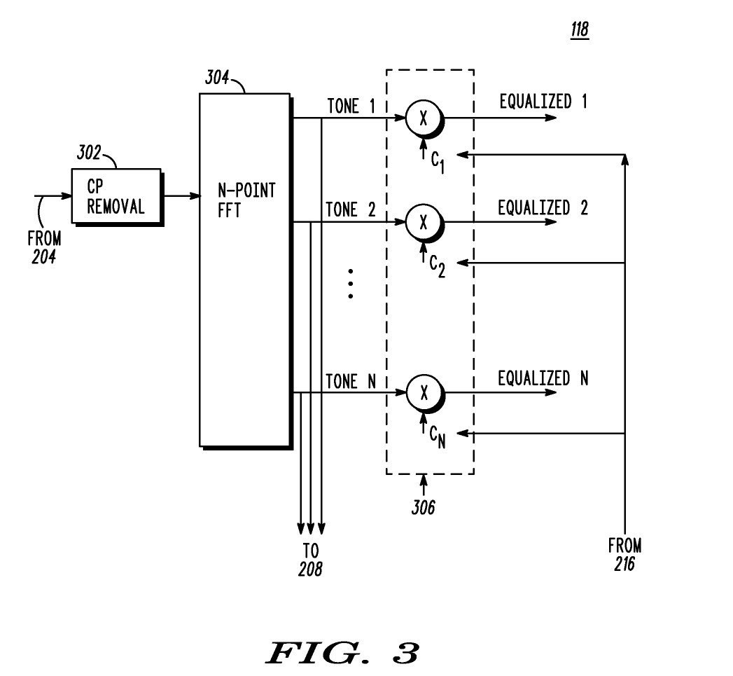

FIG. 3 is an illustration of an equalizer 118 in the frequency domain. As is commonly performed in the OFDM application, a cyclic prefix portion of the received data signal in the time domain is first removed at a cyclic prefix removal stage 302, and then the remaining signal is transformed into frequency-domain data by applying an N-point FFT (Fast Fourier Transform) operation at N-point FFT stage 304. The received data in the frequency domain, having been altered by channel distortion, is fed into a one-tap equalizer 306. The one-tap equalizer 306 has a set of coefficients or weights, C₁-C_{N}, which correspond to the N-tones of the received data in the frequency domain. In order to eliminate the distortion imposed by the channel, the coefficients are typically calculated in real time because the channel is changing constantly. A problem then lies in determining the optimal values of coefficients C1-C_{N} to achieve the best performance. As a reference design, to minimize computational complexity, these coefficients, or weights, may be derived by using a single default interpolation matrix with real-time calculated channel estimates for the pilot subcarriers, and are intended to provide a compromise estimate of the channel under all conditions for the data portions of the received signal. There is no fine-tuning of the equalizer coefficients, and this, in turn, adversely affects the individual performance of a single base station. An embodiment of the present invention uses information collected as a channel profile for the area served by the base station to determine an optimal interpolation matrix to be used in the channel estimation which, in the end, results in the derivation of these coefficients for a specific receiver, operating under pre-determined environmental conditions.

Channel distortion can be extracted from a received signal by utilizing pilot subcarriers of a signal. Because the pilot symbols are known, the pilot symbols contained in the received signal are compared to the known transmitted signal and the channel estimate is determined for that particular pilot subcarrier. But the unknown channel estimates at the data subcarrier locations (different time and frequency coordinates) need to be estimated based on the previously calculated pilot subcarriers channel estimates and the information regarding the channel condition. This can be achieved by using an interpolation matrix to interpolate the channel estimate of the actual received data subcarriers using the calculated channel estimates of the pilot subcarriers. These channel estimates of the received data carriers are then applied in the one-tap equalizer 306 to recover the actual transmitted data from the received signal.

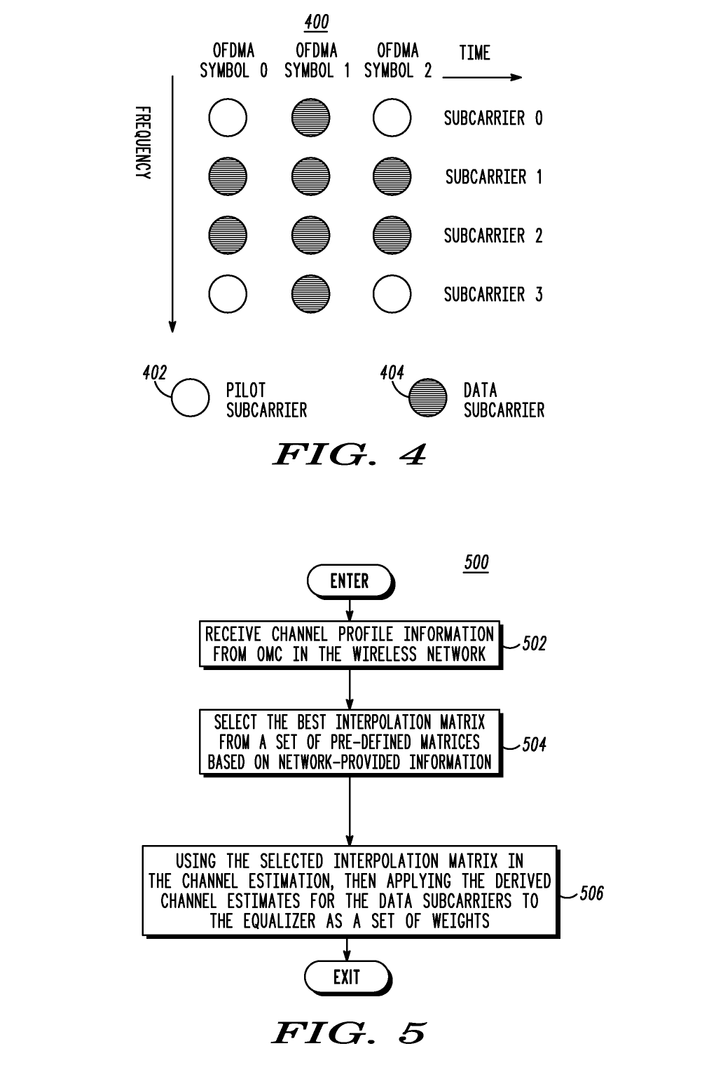

For example, FIG. 4 illustrates an uplink Partial Usage of Sub-channel (PUSC) tile structure 400. The tile contains four pilot carriers 402, in this example located in the corner positions of a 4×3 array as shown. The remaining signals 404 contain the actual data. The channel estimates for the pilot subcarriers (Ĥ_{LS}) can be determined for any received signal Rₓ, where Rₓ=y(k,n) with k being the subcarrier index and n the Orthogonal Frequency Division Multiple Access (OFDMA) symbol index and where the original transmitted signal is Tₓ=x(k,n). Thus, for the PUSC tile structure 400 of FIG. 4, the channel estimates for the pilot subcarriers are:

$${\hat{H}}_{LS} = [ \begin{matrix}\frac{y ( 0 , 0 )}{x ( 0 , 0 )} \\ \frac{y ( 3 , 0 )}{x ( 3 , 0 )} \\ \frac{y ( 0 , 2 )}{x ( 0 , 2 )} \\ \frac{y ( 3 , 2 )}{x ( 3 , 2 )}\end{matrix} ] .$$

Using a Minimum Mean-square Error (MMSE) implementation, the channel estimates for the data sub-carriers are calculated by:

$${\hat{h}}_{mmse} = {{R}_{hp} ( {R}_{pp} + \frac{β}{SNR} {I}_{N} )}^{- 1} {\hat{H}}_{ls}$$

where Rₕₚ is the cross-correlation of the pilot vector with data at the desired tile position, SNR is the signal to noise ratio, Rₚₚ is the pilot autocorrelation matrix, and β is a constant dependent only on the signal constellation. However, this implementation typically requires high computational complexity because it needs to estimate the SNR and some key channel characteristics, such as the maximum delay spread and delay profile and the maximum Doppler frequency. Therefore, this process typically is too complex to be implemented in current base station receivers at a commercially reasonable low cost.

In an embodiment of the present invention, a simplified channel estimation is made using a pre-calculated hybrid interpolation matrix (Mᵢₙₜ) with the real-time channel estimates of the pilot subcarriers Ĥ_{LS}. The following is an example of this channel estimation using a pre-defined matrix for the eight data subcarriers 404 as shown for the tile structure 400 in FIG. 4,

$$\hat{h} = {M}_{int} \cdot {\hat{H}}_{LS} = [ \begin{matrix}\frac{1}{3} & \frac{1}{6} & \frac{1}{3} & \frac{1}{6} \\ \frac{1}{6} & \frac{1}{3} & \frac{1}{6} & \frac{1}{3} \\ \frac{1}{2} & 0 & \frac{1}{2} & 0 \\ \frac{1}{3} & \frac{1}{6} & \frac{1}{3} & \frac{1}{6} \\ \frac{1}{6} & \frac{1}{3} & \frac{1}{6} & \frac{1}{3} \\ 0 & \frac{1}{2} & 0 & \frac{1}{2} \\ \frac{1}{3} & \frac{1}{6} & \frac{1}{3} & \frac{1}{6} \\ \frac{1}{6} & \frac{1}{3} & \frac{1}{6} & \frac{1}{3}\end{matrix} ] \cdot {\hat{H}}_{LS} .$$

Each different interpolation matrix will yield different performance results. No one single interpolation matrix can work well in all channel conditions.

The surrounding environment, such as the terrain and the effects of other received signals, characterizes a particular channel. Channels with similar surroundings will perform in a like manner (e.g., Typical Urban (TU), Rural Area (RA), Hilly Terrain (HT), Vehicular A (VA), etc.). Thus, by characterizing the channel behavior according to its location and surrounding environment, an optimal interpolation matrix can be selected based on the channel profile.

Turning now to FIG. 5, an operational flow diagram 500 is provided that illustrates a process of optimizing a performance of the base station receiver 120 using network assistance according to an embodiment of the present invention. The operational flow diagram 500 begins when the matrix optimizer 214 receives channel profile information 210 from the wireless network, at step 502. The channel profile information 210, in this example, is stored into the main memory 208 of the base station 112 according to the characteristics of the location of the cell site 107 during the initial deployment. The channel profile information 210 to be entered into the main memory 208 can be obtained by a variety of means. One such technique is to collect channel sounding data via drive testing. Another method is to calculate the channel profile using suitable RF network planning tools and terrain databases that can predict the channel characteristics for a local region served by a base station, such as base station 112. These are simply examples of how this information can be obtained and other techniques may be used according to the needs of the system operator, as should become obvious to those of ordinary skill in the art in view of the present discussion. The channel profile information 210 is typically assigned a code that corresponds to a particular channel type having a particular channel profile. Next, at step 504, the matrix optimizer 214 selects the best interpolation matrix 216 for the specified channel profile information 210 from a set of pre-defined interpolation matrices 218 that are based, for example, on the network provided information. Typically, each channel profile 210 is mapped to a specific interpolation matrix in the set of pre-defined interpolation matrices 218. The selected interpolation matrix 216 is then used in the channel estimation process to derive the channel estimate for the data subcarriers, and subsequently the channel estimates are then applied to the equalizer 118 as a set of weights (i.e., coefficients), at step 506. In this manner, the equalizer 118 performance is optimized for the actual channel, not a compromise for general overall performance.

Alternatively, the best interpolation matrix 216 can be found by initiating a training session to optimize the performance of the base station receiver 120. In this way, the base station receiver 120 can be fine-tuned in the field, either during the initial installation or as a part of routine maintenance and calibration.

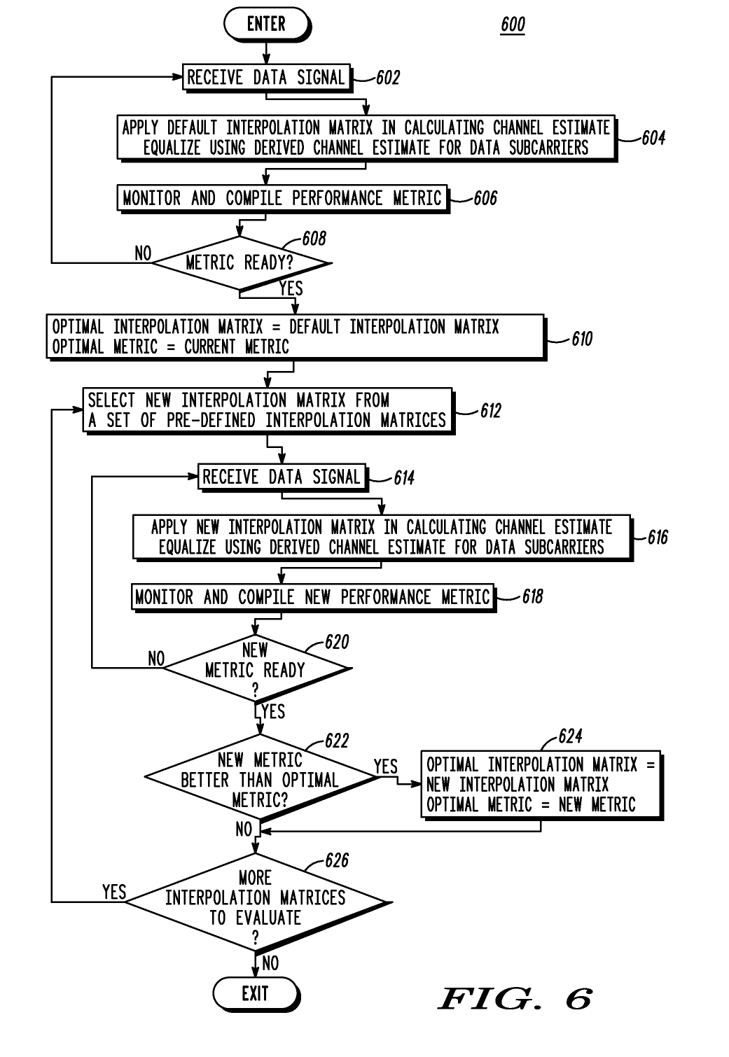

Turning now to FIG. 6, an operational flow diagram 600 is provided that illustrates another process of optimizing a performance of the base station receiver 120 using network assistance, for an example in an 802.16e system application, according to an embodiment of the present invention. Operational flow diagram 600 begins when the receiver 120 first receives a data signal, at step 602, for example, during a training session. Next, the matrix optimizer 214 applies a default interpolation matrix in the channel estimation and uses the derived channel estimates as a set of weights for the equalizer 118, at step 604. The matrix optimizer 214 monitors a selected system performance metric 212, at step 606, to evaluate the base station performance.

In order to make the performance metric statistically valid, enough metric samples should be compiled and analyzed. So if more metric samples are needed, at step 608, the steps from 602 to 606 may be repeated. The initial optimal interpolation matrix is set to the default interpolation matrix and the initial optimal metric should be set to the current metric, at step 610. If the method is being performed as part of a test drive session, the data signal received may be a known test signal and a calculated error rate (e.g., bit error rate, symbol error rate, or frame error rate) can be monitored as a desired indicator of a system performance metric. However, normal network traffic can also be monitored during routine operation to achieve the same results. In this case, standard network statistics, such as a number of dropped calls, a percentage of calls dropped, a number of access failures, or a percentage of access failures, can additionally be used in the performance metric. The performance metric can include more than one measure of performance according to the needs of the system. By way of example, the system performance metric may include a combination of a dropped call rate and a bit error rate, each with a predefined weighting in the makeup of the overall system performance metric according to the system needs.

Then, at step 612, the matrix optimizer 214 selects a different interpolation matrix from the set of pre-defined matrices 218. The receiver 120 receives another data signal, at step 614. Next, the new interpolation matrix is used in the channel estimation and subsequent equalization process, at step 616, and the selected performance metric 212 is monitored, at step 618. As before, if more metric samples are needed, at step 620, the steps from 614 to 618 may be repeated. If, at step 622, the monitored performance metric 212 is better with the new matrix than with the old matrix, that is, than with the matrix currently set as the optimal interpolation matrix, then the new matrix is selected as the optimal interpolation matrix and the new metric as the optimal metric, at step 624. Otherwise, the optimal interpolation matrix and optimal metric are not changed. This process is repeated, at step 626, for each interpolation matrix in the set of pre-defined matrices 218 until the optimal interpolation matrix 216 for use with the equalizer 118 is determined. This assures the best performance for the particular receiver equalizer 118 in the base station with a particular surrounding environment.

In view of the present discussion, performance of a base station receiver 120 can be optimized by selecting parameters from a pre-defined set of parameters associated with a plurality of channel conditions, applying the parameters in the channel estimation process, and using the results of the channel estimation in subsequent processing of a received data signal by the equalizer 118. The selection of parameters can be done by receiving channel profile information for the base station receiver 120 and selecting the parameters from a predefined set of parameters, where the selected parameters correspond to the received channel profile information. In one embodiment, the optimization of performance can be done by receiving a data signal, using parameters in a channel estimation and applying the results of the estimation to the equalizer processing, monitoring a performance metric for received data quality, and selecting optimal parameters from a predefined set of parameters based on the monitored performance metric. The base station receiver 120 can then use the selected optimal parameters in the overall channel estimation and equalization process for that particular base station 120 for the received data signal in normal network operation. In one case, the parameters can be elements of an interpolation matrix, such as in an OFDMA system application. In another case, the parameters can describe the channel characteristics, such as in a GSM/EDGE system application. Of course, some system applications may be able to take advantage of both types of parameters. The selection of parameters can include selection of parameters that are specifically tailored for particular channel characteristics from a pre-defined set of parameters. The performance metric, in one embodiment, includes one or more of the following metrics: bit error rate, symbol error rate, frame error rate, number of dropped calls, dropped call percentage, number of access failures, percentage of access failures, percentage of handover failures, and maximum capacity provided. Other metrics that can be used should become obvious to those of ordinary skill in the art in view of the present discussion. Also, the received data signal can be normal network traffic or a known test signal.

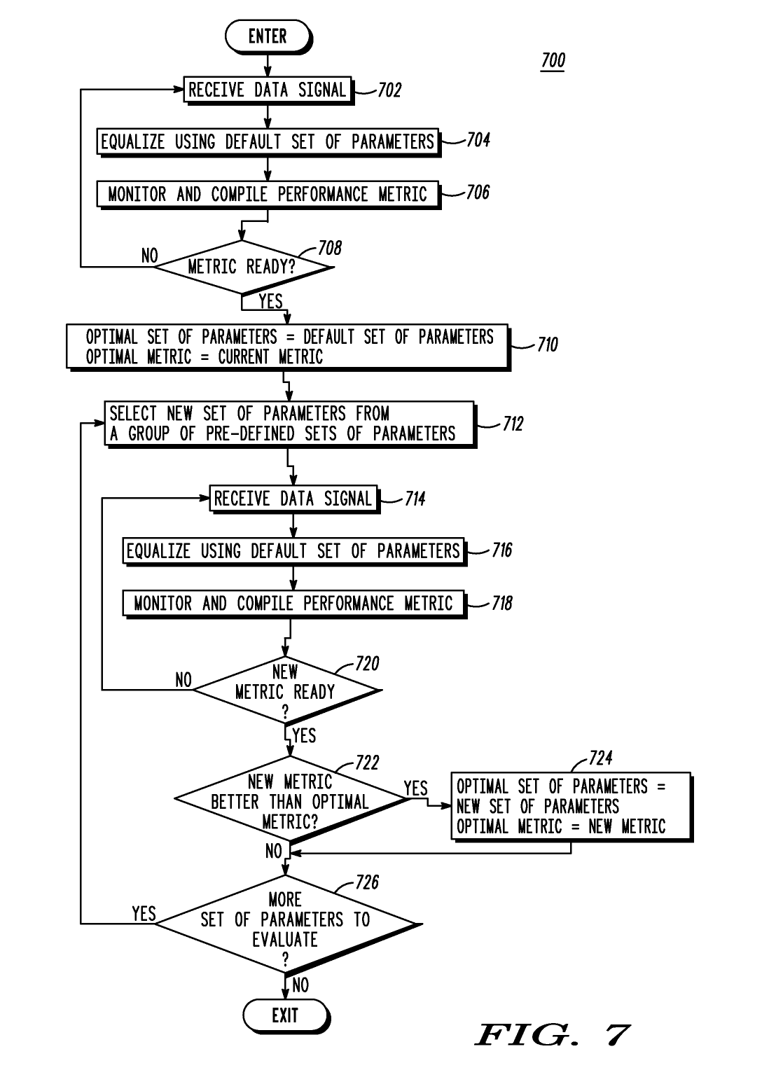

FIG. 7 is an operational flow diagram 700 illustrating another process of optimizing base station receiver performance using network assistance, for an example in a GSM/EDGE system application, according to an embodiment of the present invention. The operation flow diagram 700 is similar to the operational flow diagram 600 except that the interpolation matrix in 604, 610, 612, 616, and 624 has been replaced by a set of equalizer parameters shown in 704, 710, 712, 716, and 724. A typical set of equalizer parameters would include the information for short channel such as TU (Typical Urban Fading Profile as defined by ETSI in 3GPP TS 45.005), long channel such as HT (Hilly Terrain Fading Profile as defined by ETSI in 3GPP TS 45.005), adjacent interference dominated condition, co-channel interference dominated condition, and more such information, etc. A GSM/EDGE equalizer equipped with this channel condition information can then optimize the equalization algorithm accordingly to achieve the best possible performance. One specific example is the channel estimation portion of a GSM equalizer algorithm. If it is known that a small delay spread channel exists, such as that defined by the TU profile, the equalizer's channel estimation parameters can be selected to optimize the algorithm for short delay spread channels and minimize the noise or spurious responses that would otherwise be obtained by assuming that a large delay spread channel might be present. This will improve the receiver's performance.

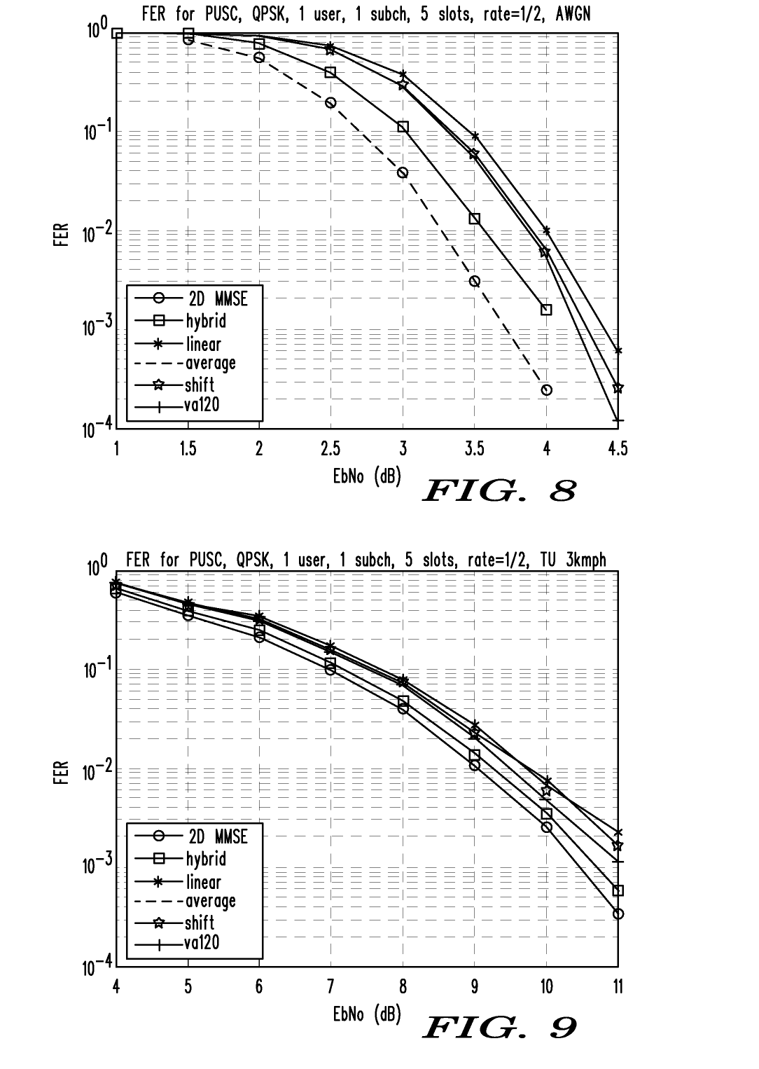

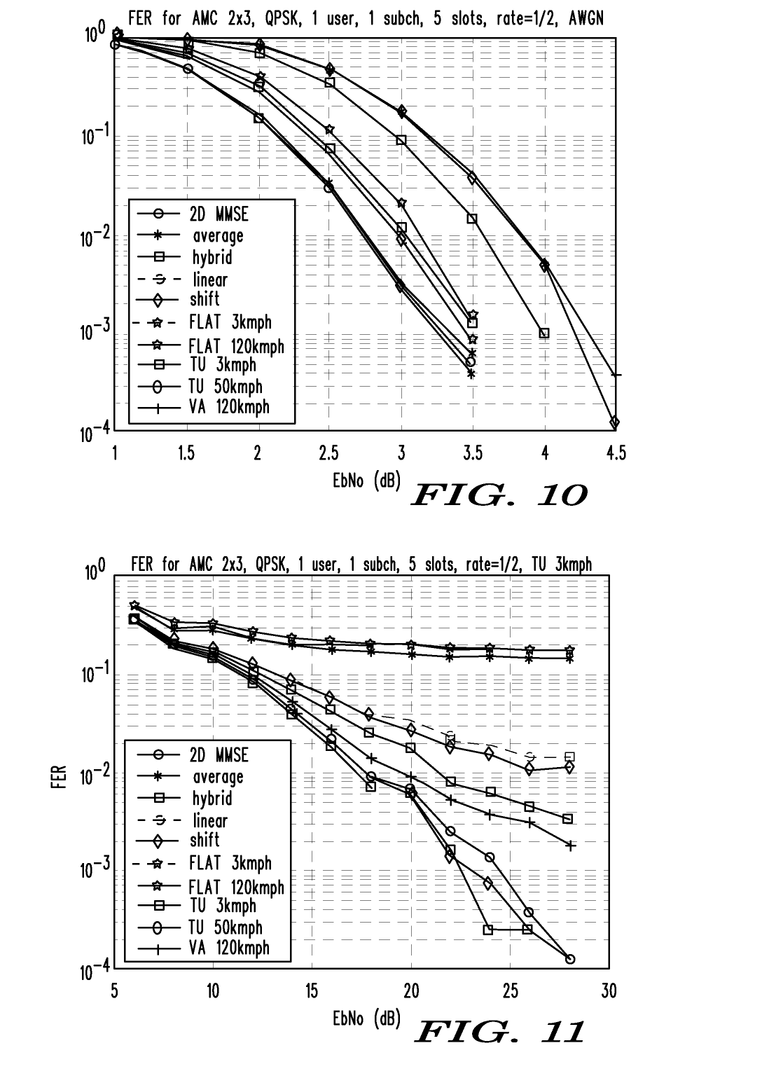

FIGS. 8, 9, 10 and 11 graphically illustrate examples of performance curves of a base station receiver, such as base station receiver 120, using various interpolation matrices. It should be obvious that the receiver performance can be greatly enhanced or degraded due to the selection of the interpolation matrix. FIG. 8 illustrates the performance curves in PUSC mode, as discussed earlier in AWGN channel condition. Note that each curve in the graph depicted in FIG. 8 represents the receiver performance using a particular interpolation matrix in the overall channel estimation and subsequent equalization process. FIG. 9 shows the performance curves in TU3 (Typical Urban Fading Profile at 3 kmph as defined by ETSI in 3GPP TS 45.005) channel condition for the same set of pre-defined interpolation matrices in PUSC mode. The performance difference between the different interpolation matrices is relatively modest due to the high pilot density (⅓, or one pilot subcarrier per three subcarriers) in the PUSC mode. However, the possible difference in performance can be quite substantial in the alternative case, shown in FIGS. 10 and 11, where AMC (Adaptive Modulation and Coding) 2×3 mode is used. In the case of AMC 2×3, the data and pilot carriers are arranged in a different fashion so that there are 18 tones×3 symbols per tone, or 54 possible symbol locations. However, there are only 6 pilots, so the pilot density is 1/9 and the data are far apart. As shown in FIGS. 10 and 11, no one particular interpolation matrix can yield best performance in different channel conditions such as AGWN and TU3 as presented. Thus, it is important to have the proper interpolation matrix to derive better channel estimates for the data subcarriers, and these channel estimates can then be used in the equalizer for the particular application in order for the data estimates to be good. Note that in FIGS. 9 and 11, the simulated channel condition is TU3 and each curve represents a special interpolation matrix used in the overall channel estimation and equalization process.

The improved receiver sensitivity performance attained by the implementation of the present invention often translates to improvements in coverage area, a need for fewer base stations during deployment, better voice quality, and higher data throughput.

Non-Limiting Examples

Although specific embodiments of the invention have been disclosed, those having ordinary skill in the art will understand that changes can be made to the specific embodiments without departing from the spirit and scope of the invention. The scope of the invention is not to be restricted, therefore, to the specific embodiments, and it is intended that the appended claims cover any and all such applications, modifications, and embodiments within the scope of the present invention.

For example, as has been discussed above, FIG. 7 is a version of the process shown that FIG. 6 that is useful for a GSM/EDGE system application. A GSM/EDGE equalizer and system equipped with this channel condition information can then optimize the equalization process accordingly to achieve the best possible performance. One specific example is the channel estimation portion of a GSM equalizer algorithm. If it is known that a small delay spread channel exists, such as that defined by the TU profile, the equalizer's channel estimation parameters can be selected to optimize the algorithm for short delay spread channels and minimize the noise or spurious responses that would otherwise be obtained by assuming that a large delay spread channel might be present. This will significantly improve the receiver's performance. This is only one specific example and others are readily identified by one of ordinary skill in the art in view of the present discussion.

What is claimed is:

1. A method, in a wireless communication system, for optimizing performance of a base station receiver, the method comprising:
selecting parameters from a pre-defined set of parameters associated with a plurality of channel conditions;
applying the parameters in the channel estimation process; and
using the results of the channel estimation in subsequent equalizer processing of a received data signal.

2. The method of claim 1, wherein the selecting parameters from a pre-defined set of parameters comprises:
receiving channel profile information for the base station receiver; and
selecting the parameters from a predefined set of parameters, the selected parameters corresponding to the received channel profile information.

3. The method of claim 1, wherein the selecting parameters comprises:
receiving a data signal;
using parameters in a channel estimation and applying the results of the estimation to the equalizer processing;
monitoring a performance metric for received data quality; and
selecting optimal parameters from a predefined set of parameters based on the monitored performance metric; and
wherein the using the results comprises using the selected optimal parameters in the overall channel estimation and equalization process for that particular base station for the received data signal in normal network operation.

4. The method of claim 1, wherein at least one of:
the parameters are elements of an interpolation matrix; and
the parameters describe the channel characteristics.

5. The method of claim 3, wherein the performance metric comprises one or more of a bit error rate, a symbol error rate, a frame error rate, a number of dropped calls, a dropped call percentage, a number of access failures, a percentage of access failures, a percentage of handover failures, and a maximum capacity provided.

6. The method of claim 3, wherein the received data signal is one of:
a known test signal; and
normal network traffic.

7. A wireless communication system comprising:
a plurality of wireless devices;
a cell site communicatively coupled to the plurality of wireless devices; and
a base station servicing the cell site, wherein the base station comprises:
a receiver;
an equalizer communicatively coupled to the receiver; and
an optimizer communicatively coupled to the equalizer, for performing the steps of:
selecting parameters specifically tailored for particular channel characteristics from a pre-defined set of parameters;
using the selected parameters in the channel estimation; and
using the results of the channel estimation in subsequent equalizer processing of the data signal.

8. The wireless communication system of claim 7, wherein the selecting of parameters from a pre-defined set of parameters associated with a plurality of channel conditions comprises:
receiving channel profile information for the base station receiver from at least one of:
an operations and maintenance center; and
a local maintenance terminal coupled to the base station; and
selecting the parameters from a predefined set of parameters, the selected parameters corresponding to the received channel profile information.

9. The wireless communication system of claim 7, wherein the selecting of parameters and using them in a channel estimation from a predefined set of parameters, comprises:
receiving a data signal;
using parameters in a channel estimation and applying the results of the estimation to the equalizer processing;
monitoring a performance metric for received data quality;
selecting optimal parameters from a predefined set of parameters based on the monitored performance metric; and
using the selected optimal parameters in the overall channel estimation and equalization for that particular base station for the received data signal in normal network operation.

10. The wireless communication system of claim 7, wherein one or more of:
the parameters are elements of an interpolation matrix for use by the at least one base station in an Orthogonal Frequency Division Multiplexing communication system; and
the parameters describe the channel characteristics for use by the at least one base station in a Time Division Multiple Access communication system.

11. The wireless communication system of claim 9, wherein the performance metric is one or more of a bit error rate, a symbol error rate, a frame error rate, a number of dropped calls, a dropped call percentage, a number of access failures, a percentage of access failures, a percentage of handover failures, and a maximum capacity provided.

12. The communication system of claim 9, wherein the received data signal is one of:
a known test signal; and
normal network traffic.

13. A base station, for communicatively coupling to a cell site, the base station comprising:
a receiver;
an equalizer, communicatively coupled to the receiver; and
an optimizer, communicatively coupled to the equalizer, for performing the steps of:
selecting parameters specifically tailored for particular channel characteristics from a pre-defined set of parameters;
using the selected parameters in the channel estimation; and
using the results of the channel estimation in subsequent equalizer processing of the data signal.

14. The base station of claim 13, wherein the parameters are elements of an interpolation matrix.

15. The base station of claim 13, wherein the parameters describe the channel characteristics.

16. The base station of claim 13, wherein the selecting of parameters from a pre-defined set of parameters associated with a plurality of channel conditions comprises:
receiving channel profile information for the base station receiver; and
selecting the parameters from a predefined set of parameters, the selected parameters corresponding to the received channel profile information.

17. The base station of claim 13, wherein the selecting of parameters and using them in a channel estimation from a predefined set of parameters, comprises:
receiving a data signal;
using parameters in a channel estimation and applying the results of the estimation to the equalizer processing;
monitoring a performance metric for received data quality;
selecting optimal parameters from a defined set of parameters based on the monitored performance metric; and
using the selected optimal parameters in the overall channel estimation and equalization for that particular base station for the received data signal in normal network operation.

18. The base station of claim 17, wherein the performance metric is one or more of a bit error rate, a symbol error rate, a frame error rate, a number of dropped calls, a dropped call percentage, a number of access failures, a percentage of access failures, a percentage of handover failures, and a maximum capacity provided.

19. The base station of claim 17, wherein the received data signal is a known test signal.

20. The base station of claim 18, wherein the received data signal is normal network traffic.
